(19) United States
(12) Patent Application Publication
(10) Pub. No.: US 2026/0198393 A1
(43) Pub. Date: Jul. 9, 2026

(54) Power Semiconductor Device

(71) Applicant: Astemo, Ltd., Chiyoda-ku, Tokyo (JP)

(72) Inventors: Shintaro TANAKA, Tokyo (JP); Takeshi TOKUYAMA, Tokyo (JP); Hironori NAGASAKI, Tokyo (JP); Kyota ASAI, Tokyo (JP); Takahiro SHIMURA, Hitachinaka-shi, Ibaraki (JP)

(21) Appl. No.: 19/132,160

(22) PCT Filed: Aug. 24, 2023
(86) PCT No.: PCT/JP2023/030625

§ 371 Date: May 22, 2025

(30) Foreign Application Priority Data
Nov. 22, 2022 (JP) 2022-186757

(51) Int. Cl. H10W 90/00; H02M 7/00; H10W 70/40; H10W 72/00; H10W 72/30; H10W 90/10

(52) U.S. Cl. CPC H10W 90/811; H02M 7/003; H10W 70/424; H10W 70/481; H10W 72/347; H10W 90/10; H10W 90/736; H10W 72/865; H10W 72/884; H10W 90/756

(57) ABSTRACT

A power conversion device includes: a plurality of upper arm side power semiconductor elements and a plurality of lower arm side power semiconductor elements; a first conductor and a second conductor connected to the upper arm side power semiconductor elements; and a third conductor and a fourth conductor connected to the lower arm side power semiconductor elements, an upper arm side merging portion is provided at positions at equal distances from the plurality of upper arm side power semiconductor elements, a lower arm side merging portion is provided at positions at equal distances from the plurality of lower arm side power semiconductor elements, and the upper arm side merging portion and the lower arm side merging portion are disposed adjacent to a region between an arrangement row of the plurality of upper arm side power semiconductor elements and an arrangement row of the plurality of lower arm side power semiconductor elements.

### TECHNICAL FIELD

The present invention relates to a power semiconductor device.

### BACKGROUND ART

While development of a power module using highly efficient silicon carbide (SiC) has been advanced, parallelized implementation of chips is commonly employed since such a power module cannot increase a chip size as compared with an insulated gate bipolar transistor (IGBT). Along with the practical realization of such parallelized implementation of chips, downsizing of a cooling structure for suppressing current imbalance between chips and suppressing an amount of heat generation is also demanded at the same time.

For example, PTL 1 listed below discloses a configuration of a power conversion device having a high operating voltage, where a total value of drains and source inductances between chips is equalized by providing a structure of a laminated conductor in which a diameter of a pit of a plate-shaped conductor or a size of a plate-shaped conductor to be disconnected from a connection member are reduced and inductance is reduced.

### CITATION LIST

### Patent Literature

PTL 1: Japanese Patent No. 3550970

### SUMMARY OF INVENTION

### Technical Problem

In the configuration of PTL 1, the source inductance is equal only at the upper arm and there is a source inductance difference between chips on the lower arm side, and therefore a loss increase due to current imbalance occurs under a high-speed switching condition of SiC. In view of such circumstances, an object of the present invention is to provide a current conversion device capable of reducing an inductance difference and suppressing a current imbalance.

### Solution to Problem

A power semiconductor device includes: a plurality of upper arm side power semiconductor elements and a plurality of lower arm side power semiconductor elements electrically connected in parallel; a first conductor and a second conductor, the first conductor being connected to high potential side electrodes of the upper arm side power semiconductor elements, the second conductor being connected to low potential side electrodes of the upper arm side power semiconductor elements; and a third conductor and a fourth conductor, the third conductor being connected to high potential side electrodes of the lower arm side power semiconductor elements, the fourth conductor being connected to low potential side electrodes of the lower arm side power semiconductor elements, wherein in the second conductor, an upper arm side merging portion at which currents flowing from the low potential side electrodes of the upper arm side power semiconductor elements merge is provided at positions at equal distances from the plurality of upper arm side power semiconductor elements, in the fourth conductor, a lower arm side merging portion at which currents flowing from the low potential side electrodes of the lower arm side power semiconductor elements merge is provided at positions at equal distances from the plurality of lower arm side power semiconductor elements, and the upper arm side merging portion and the lower arm side merging portion are disposed adjacent to a region between an arrangement row of the plurality of upper arm side power semiconductor elements and an arrangement row of the plurality of lower arm side power semiconductor elements.

### Advantageous Effects of Invention

It is possible to provide a current conversion device capable of reducing an inductance difference and suppressing a current imbalance.

### BRIEF DESCRIPTION OF DRAWINGS

FIG. 1 is a diagram of a semiconductor device in a power conversion device according to an embodiment of the present invention.

FIG. 2 is an explanatory diagram of a semiconductor element mounted on the power conversion device of FIG. 1.

FIG. 3 is a cross-sectional view taken along line A-A′ of FIG. 2.

FIG. 4 is an electric circuit diagram of the power conversion device.

FIG. 5 is an explanatory diagram of a semiconductor element mounted on the power conversion device.

FIG. 6 shows a first modified example.

FIG. 7 shows a second modified example.

FIG. 8 shows a third modified example.

Hereinafter, an embodiment of the present invention will be described with reference to the drawings. The following description and drawings are examples for describing the present invention, and omission and simplification are made as appropriate for the sake of clarity of description. The present invention can be carried out in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the positions, sizes, shapes, ranges, and the like disclosed in the drawings.

### (Overall Configuration of Embodiment and Device of Present Invention)

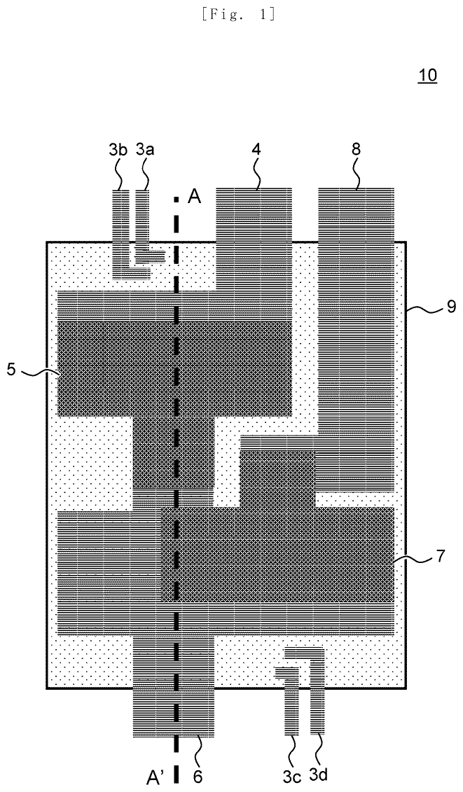

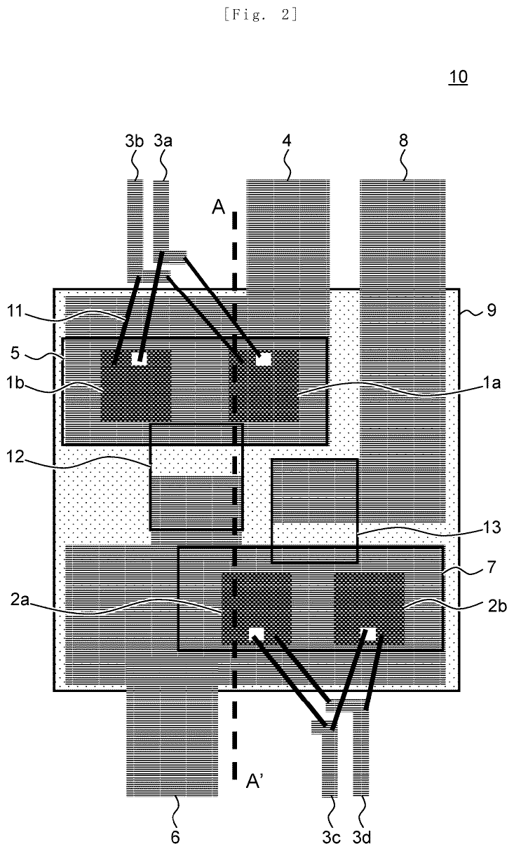

### (FIGS. 1 and 2)

In a power semiconductor device 10 included in a power conversion device, a plurality of upper arm side power semiconductor elements and a plurality of lower arm side power semiconductor elements are electrically connected in parallel. In the present invention, one set of the upper arm side power semiconductor element and the lower arm side power semiconductor element is illustrated. In addition, in the description of FIG. 2 and subsequent figures, the upper arm side power semiconductor elements are described as power semiconductors 1a and 1b, and the lower arm side power semiconductor elements are described as power semiconductors 2a and 2b. The power semiconductors 1a, 1b, 2a, and 2b are, for example, IGBTs, SiC-MOSFETS, GaN-HEMTs (High Electron Mobility Transistors), and the like.

The power semiconductor device 10 includes a first conductor 4, a second conductor 5, a third conductor 6, a fourth conductor 7, and a fifth conductor 8 that are main circuit conductors, a first signal terminal 3a, a second signal terminal 3b, a third signal terminal 3c, and a fourth signal terminal 3d that transmit control signals of the power semiconductors 1a, 1b, 2a, and 2b (FIG. 2), and a mold resin 9 that seals the above components.

The first signal terminal 3a transmits drive signals of the power semiconductors 1a and 1b connected to the first conductor 4 and the second conductor 5. The first conductor 4 is connected to high potential side electrodes of the upper arm side power semiconductor elements 1a and 1b. The second conductor 5 is connected to low potential side electrodes of the upper arm side power semiconductor elements 1a and 1b. The first signal terminal 3a is connected to signal electrodes of the power semiconductors 1a and 1b by a bonding material such as a wire 11. On the other hand, the second signal terminal 3b is connected to the low potential side electrodes of the power semiconductors 1a and 1b by a bonding material such as the wire 11.

The third signal terminal 3c transmits drive signals of the power semiconductors 2a and 2b connected to the third conductor 6 and the fourth conductor 7. The third conductor 6 is connected to high potential side electrodes of the lower arm side power semiconductor elements 2a and 2b. The fourth conductor 7 is connected to low potential side electrodes of the lower arm side power semiconductor elements 2a and 2b. The third signal terminal 3c is connected to signal electrodes of the power semiconductors 2a and 2b by a bonding material such as the wire 11. On the other hand, the fourth signal terminal 3d is connected to the low potential side electrodes of the power semiconductors 2a and 2b by a bonding material such as the wire 11.

The high potential side electrodes of the plurality of power semiconductors 1a and 1b and the first conductor 4 are bonded by a bonding material such as solder. The low potential side electrodes of the plurality of power semiconductors 1a and 1b and the second conductor 5 are bonded by a bonding material such as solder. The second conductor 5 and the third conductor 6 are bonded by a bonding material such as solder.

The high potential side electrodes of the plurality of power semiconductors 2a and 2b and the third conductor 6 are bonded by a bonding material such as solder. The low potential side electrodes of the plurality of power semiconductors 2a and 2b and the fourth conductor 7 are bonded by a bonding material such as solder. The fourth conductor 7 and the fifth conductor 8 are bonded by a bonding material such as solder.

On the second conductor 5 electrically connected between the low potential side electrodes of the power semiconductors 1a and 1b and the third conductor 6, an upper arm side merging portion 12 at which currents flowing respectively from the low potential side electrodes of the upper arm side power semiconductors 1a and 1b merge is provided. The second conductor 5 is provided at a position where lengths from the power semiconductors 1a and 1b to the upper arm side merging portion 12 are the same in order to equalize distances of the currents flowing respectively from the low potential side electrodes of the power semiconductors 1a and 1b to the upper arm side merging portion 12.

Similarly, on the fourth conductor 7 electrically connected between the low potential side of the power semiconductors 2a and 2b and the fifth conductor 8, a lower arm side merging portion 13 at which currents flowing respectively from the low potential side electrodes of the lower arm side power semiconductors 2a and 2b merge is provided. The second conductor 5 is provided at a position where lengths from the power semiconductors 2a and 2b to the lower arm side merging portion 13 are the same in order to equalize distances of the currents flowing respectively from a side of the low potential electrodes of the power semiconductors 2a and 2b to the lower arm side merging portion 13.

As a result, the inductances of the parasitic components due to the wiring distances become equal, the gate potentials generated between the sources at the time of switching become equal, the current imbalance can be suppressed, and a loss associated with the switching can be reduced. Thus, the currents flowing through the power semiconductors 1a and 1b and the power semiconductors 2a and 2b are made uniform.

The upper arm side merging portion 12 and the lower arm side merging portion 13 are disposed adjacent to each other with a predetermined space interposed therebetween in a region between an arrangement row of the plurality of upper arm side power semiconductor elements 1a and 1b and an arrangement row of the plurality of lower arm side power semiconductor elements 2a and 2b, and are disposed such that directions of the current flowing through the upper arm side merging portion 12 and the direction of the current flowing through the lower arm side merging portion 13 are opposite from each other. As a result, the parasitic inductance of a main circuit is reduced by the counter current cancelling the magnetic flux, and the heat dissipation between the upper arm side merging portion 12 and the lower arm side merging portion 13 is reduced. In addition, by reducing an amount of heat generated between the semiconductor elements, downsizing of the cooling structure can be realized.

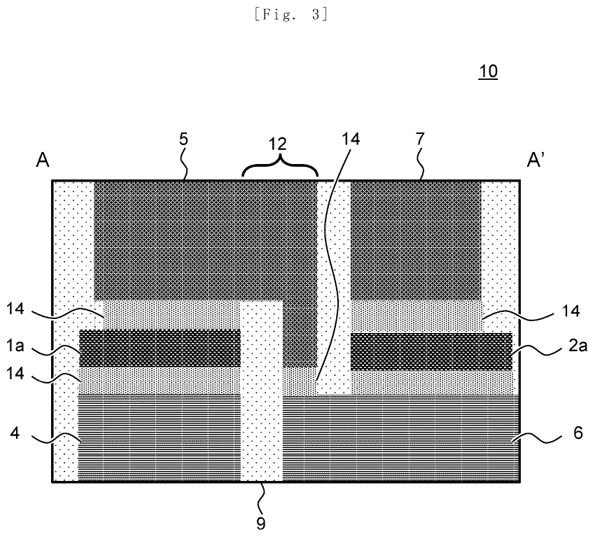

### (FIG. 3)

In the power semiconductor device 10, the high potential side electrode of the first power semiconductor 1a and the first conductor 4 are bonded by a bonding material 14 such as solder, and the low potential side electrode of the power semiconductor 1a and the second conductor 5 are bonded by the bonding material 14 such as solder. The second conductor 5 and the third conductor 6 are bonded by the bonding material 14 such as solder. Similarly, the high potential side electrode of the second power semiconductor 2a and the third conductor 6 are bonded by the bonding material 14 such as solder, and the low potential side electrode of the power semiconductor 2a and the fourth conductor 7 are bonded by the bonding material 14 such as solder.

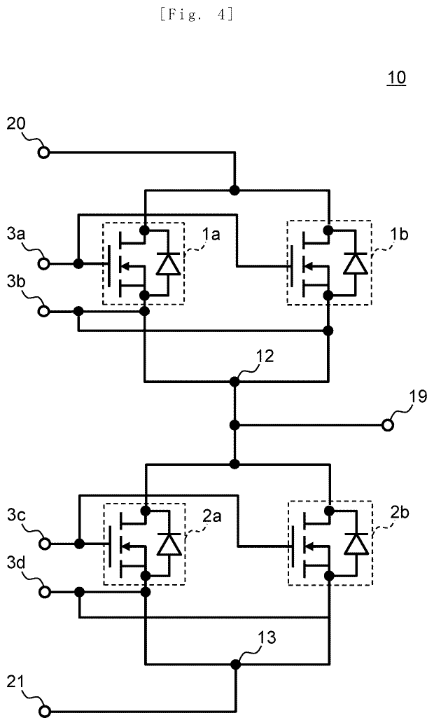

### (FIG. 4)

Each of the power semiconductor elements 1a, 1b, 2a, and 2b has three terminals including a main circuit high voltage side terminal (a collector terminal for IGBT, and a drain terminal for MOSFET), a main circuit low voltage side terminal (an emitter terminal for IGBT, and a source terminal for MOSFET), and a control terminal (gate terminal). Note that the power semiconductor elements 1a, 1b, 2a, and 2b may be further connected in multiple and parallel according to a desired output current value, or the power semiconductor device 10 itself may be connected in multiple and parallel.

A positive electrode wiring 20 is connected to a positive electrode terminal of a DC voltage source such as a battery (not shown), and a negative electrode wiring 21 is connected to a negative electrode terminal of the DC voltage source such as a battery (not shown). Accordingly, a DC voltage is supplied to the power semiconductor device 10.

The positive electrode wiring 20 is connected to the main circuit high voltage side terminals of the power semiconductor elements 1a and 1b. The main circuit low voltage side terminals of the power semiconductor elements 1a and 1b are connected to an output terminal 19 of the power semiconductor device 10 via the upper arm side merging portion 12. Further, the main circuit low voltage side terminals of the power semiconductor elements 1a and 1b are connected in parallel to the main circuit high voltage side terminals of the power semiconductor elements 2a and 2b. The main circuit low voltage side terminals of the power semiconductor elements 2a and 2b are connected to the negative electrode wiring 21 via the lower arm side merging portion 13.

The output terminal 19 of the power semiconductor elements 1a, 1b, 2a, and 2b is connected to a load such as a motor. The first signal terminal 3a to the fourth signal terminal 3d, which are the control terminals of the power semiconductor devices 1a, 1b, 2a, and 2b, are connected to a control circuit (not illustrated), and are turned on or off on the basis of a signal input from a high-order control device such as a microcomputer, and thus an AC voltage is output to a load such as a motor via the output terminal 19.

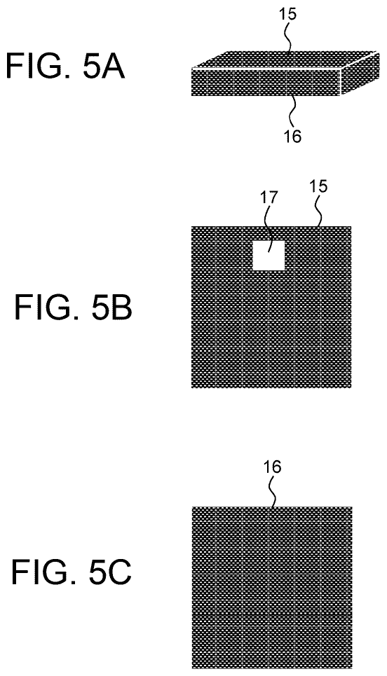

### (FIG. 5)

FIG. 5(a) is a perspective view of a power semiconductor element, FIG. 5(b) is a view of FIG. 5(a) as viewed from one surface, and FIG. 5(c) is a view of FIG. 5(a) as viewed from the other surface. Each of the first power semiconductors 1a and 1b and the second power semiconductors 2a and 2b includes a power semiconductor low potential electrode 15, a power semiconductor high potential side electrode 16, and a power semiconductor signal electrode 17 to which a drive signal of the power semiconductor is applied.

### First Modified Example

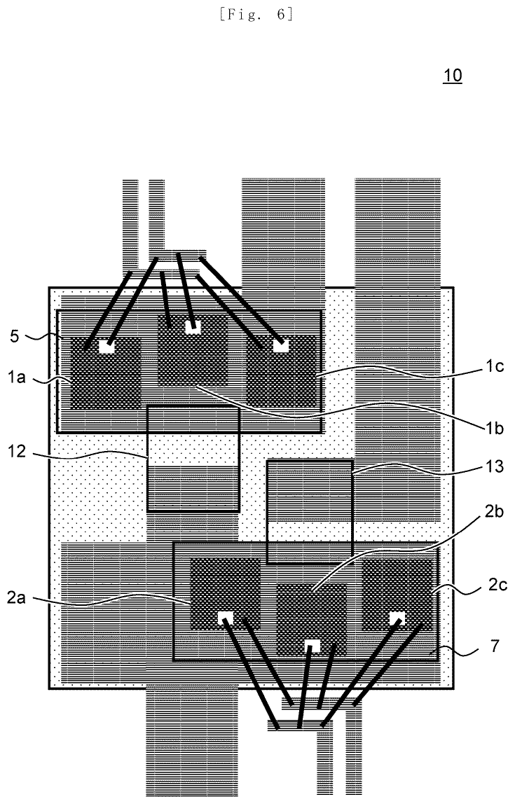

### (FIG. 6)

The second conductor 5 includes power semiconductors 1a, 1b, and 1c. The fourth conductor 7 includes power semiconductors 2a, 2b, and 2c. The second conductor 5 is disposed such that distances of currents flowing between the power semiconductors 1a, 1b, and 1c and the upper arm side merging portion 12 are equal. In addition, the fourth conductor 7 is disposed such that distances of currents flowing between the power semiconductors 2a, 2b, and 2c and the upper arm side merging portion 12 are equal. As a result, it is possible to obtain the same operational effects as those of the embodiment in which the second conductor 5 includes the power semiconductors 1a and 1b and the fourth conductor 7 includes the power semiconductors 2a and 2b.

### Second Modified Example

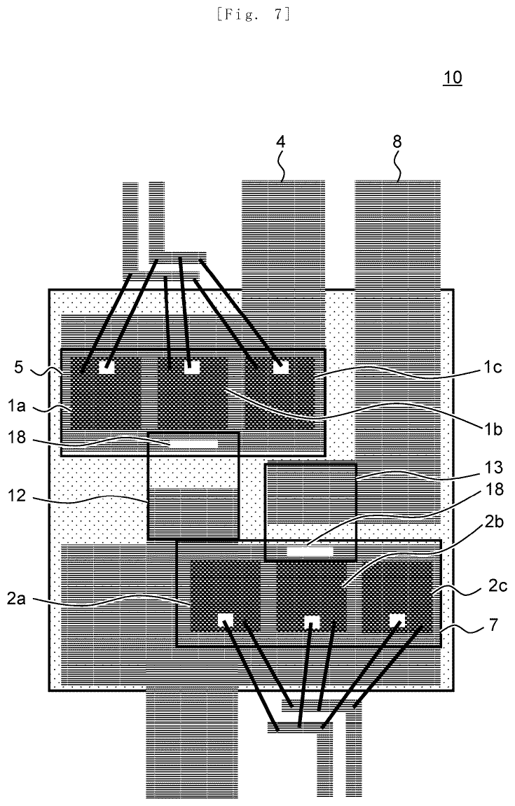

### (FIG. 7)

In the first modified example of FIG. 6 in which the second conductor 5 includes the power semiconductors 1a, 1b, and 1c and the fourth conductor 7 includes the power semiconductors 2a, 2b, and 2c, a slit 18 is provided between the low potential side electrode of the power semiconductor 1b and the upper arm side merging portion 12, and the slit 18 is provided between the low potential side electrode of the power semiconductor 2b and the lower arm side merging portion 13. As a result, a current path from the power semiconductor 1b electrically at a higher potential than the slit 18 to the upper arm side merging portion 12 becomes long, and the parasitic inductances due to the wiring distances of the power semiconductors 1a and 1c and the power semiconductor 1b become equal. Similarly, a current path from the power semiconductor 2b electrically at a higher potential than the slit 18 to the lower arm side merging portion 13 becomes long, and the parasitic inductances due to the wiring distances of the power semiconductors 2a and 2c and the power semiconductor 2b become equal. Therefore, the currents flowing through the power semiconductors 1a to 1c and the power semiconductors 2a to 2c are made uniform. Further, it is possible to suppress the current imbalance between the power semiconductor elements.

### Third Modified Example

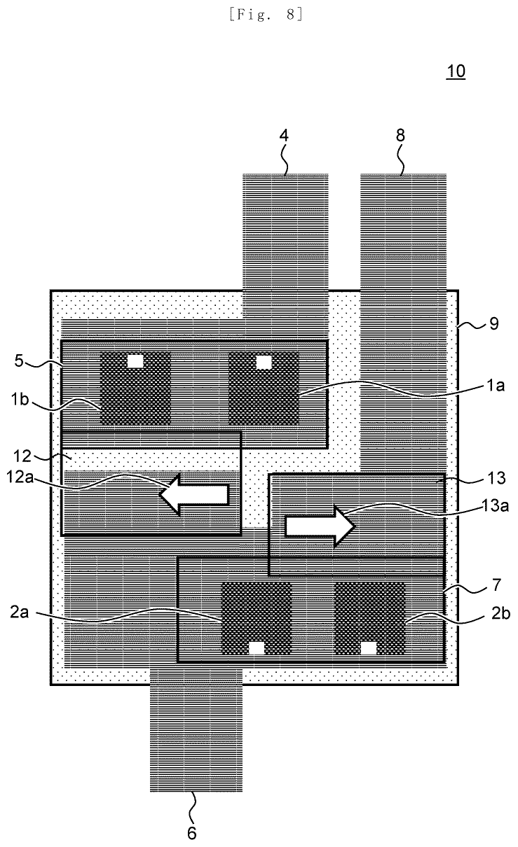

### (FIG. 8)

The upper arm side merging portion 12 and the lower arm side merging portion 13 may be provided by expanding toward directions opposite from directions in which the upper arm side merging portion and the lower arm side merging portion facing each other, that is, toward an expansion direction 12a of the upper arm side merging portion and an expansion direction 13a of the lower arm side merging portion, respectively. As a result, the current path of the upper arm side merging portion 12 is extended, and the parasitic inductance of the second conductor 5 is reduced. Similarly, the current path of the lower arm side merging portion 13 is extended, and the parasitic inductance of the fourth conductor 7 is reduced. Therefore, this contributes to reduction of the parasitic inductance of the entire power semiconductor device 10.

The second conductor 5 and the fourth conductor 7 may be formed in the same shape. With this, it is possible to realize facilitation and cost reduction of manufacturing by standardization of parts.

According to the embodiment of the present invention described above, the following effects and advantages are obtained.
(1) A power conversion device includes: a plurality of upper arm side power semiconductor elements 1a and 1b and a plurality of lower arm side power semiconductor elements 2a and 2b electrically connected in parallel; a first conductor 4 and a second conductor 5, the first conductor 4 being connected to high potential side electrodes of the upper arm side power semiconductor elements 1a and 1b, the second conductor 5 being connected to low potential side electrodes of the upper arm side power semiconductor elements 1a and 1b; and a third conductor 6 and a fourth conductor 7, the third conductor 6 being connected to high potential side electrodes of the lower arm side power semiconductor elements 2a and 2b, the fourth conductor 7 being connected to low potential side electrodes of the lower arm side power semiconductor elements 2a and 2b. In the second conductor 5, an upper arm side merging portion 12 at which currents flowing from the low potential side electrodes of the upper arm side power semiconductor elements 1a and 1b merge is provided at positions at equal distances from the plurality of upper arm side power semiconductor elements 1a and 1b. In the fourth conductor 7, a lower arm side merging portion 13 at which currents flowing from the low potential side electrodes of the lower arm side power semiconductor elements 2a and 2b merge is provided at positions at equal distances from the plurality of lower arm side power semiconductor elements 2a and 2b. The upper arm side merging portion 12 and the lower arm side merging portion 13 are disposed adjacent to a region between an arrangement row of the plurality of upper arm side power semiconductor elements 1a and 1b and an arrangement row of the plurality of lower arm side power semiconductor elements 2a and 2b. With this configuration, it is possible to provide a current conversion device in which the inductance difference is reduced and the current imbalance is suppressed.
(2) The upper arm side merging portion 12 and the lower arm side merging portion 13 are disposed such that directions of currents flowing therethrough are opposite from each other. With this configuration, the parasitic inductance of the main circuit is reduced by the counter current cancelling the magnetic flux, and the heat dissipation between the upper arm side merging portion 12 and the lower arm side merging portion 13 is reduced. In addition, by reducing an amount of heat generated between the semiconductor elements, downsizing of the cooling structure can be realized.
(3) A slit portion 18 is provided between the second conductor 5 and the upper arm side merging portion 12 and between the fourth conductor 7 and the lower arm side merging portion 13. With this configuration, the parasitic inductances due to the wiring distances of the power semiconductors 1a and 1c to the power semiconductor 1b become equal.
(4) A plurality of the upper arm side merging portions 12 and a plurality of the lower arm side merging portions 13 are provided by expanding toward directions opposite from directions in which the upper arm side merging portion and the lower arm side merging portion facing each other. This configuration contributes to reduction of the parasitic inductance of the entire power semiconductor device 10.
(5) The second conductor 5 and the fourth conductor 7 have an identical shape. With this configuration, by standardization of parts, it is possible to facilitate manufacturing and to reduce manufacturing costs.

Note that the present invention is not limited to the above embodiment, and various modifications and other configurations can be combined without departing from the gist of the present invention. In addition, the present invention is not limited to a case including all the configurations described in the above embodiment, and includes a case in which a part of the configurations is omitted.

### REFERENCE SIGNS LIST

1a, 1b, 1c first power semiconductor
2a, 2b, 2c second power semiconductor
3 signal terminal
3a first signal terminal
3b second signal terminal
3c third signal terminal
3d fourth signal terminal
4 first conductor
5 second conductor
6 third conductor
7 fourth conductor
8 fifth conductor
9 mold resin
10 power semiconductor device
11 wire
12 upper arm side merging portion
12a expansion direction of upper arm side merging portion
13 lower arm side merging portion
13a expansion direction of lower arm side merging portion
14 bonding material
15 power semiconductor low potential electrode
16 power semiconductor high potential electrode
17 power semiconductor signal electrode
18 slit
19 output terminal
20 positive electrode wiring
21 negative electrode wiring

1. A power semiconductor device comprising:
a plurality of upper arm side power semiconductor elements and a plurality of lower arm side power semiconductor elements electrically connected in parallel;
a first conductor and a second conductor, the first conductor being connected to high potential side electrodes of the upper arm side power semiconductor elements, the second conductor being connected to low potential side electrodes of the upper arm side power semiconductor elements; and
a third conductor and a fourth conductor, the third conductor being connected to high potential side electrodes of the lower arm side power semiconductor elements, the fourth conductor being connected to low potential side electrodes of the lower arm side power semiconductor elements,
wherein
in the second conductor, an upper arm side merging portion at which currents flowing from the low potential side electrodes of the upper arm side power semiconductor elements merge is provided at positions at equal distances from the plurality of upper arm side power semiconductor elements,
in the fourth conductor, a lower arm side merging portion at which currents flowing from the low potential side electrodes of the lower arm side power semiconductor elements merge is provided at positions at equal distances from the plurality of lower arm side power semiconductor elements, and
the upper arm side merging portion and the lower arm side merging portion are disposed adjacent to a region between an arrangement row of the plurality of upper arm side power semiconductor elements and an arrangement row of the plurality of lower arm side power semiconductor elements.

2. The power semiconductor device according to claim 1, wherein the upper arm side merging portion and the lower arm side merging portion are disposed such that directions of currents flowing therethrough are opposite from each other.

3. The power semiconductor device according to claim 1, wherein a slit portion is provided between the second conductor and the upper arm side merging portion and between the fourth conductor and the lower arm side merging portion.

4. The power semiconductor device according to claim 1, wherein a plurality of the upper arm side merging portions and a plurality of the lower arm side merging portions are provided by expanding toward directions opposite from directions in which the upper arm side merging portion and the lower arm side merging portion facing each other.

5. The power semiconductor device according to claim 1, wherein the second conductor and the fourth conductor have an identical shape.
